(19) United States
(12) Patent Application Publication
(10) Pub. No.: US 2022/0386479 A1
(43) Pub. Date: Dec. 1, 2022

(54) BATCH JOINING TYPE MULTI-LAYER PRINTED CIRCUIT BOARD AND MANUFACTURING METHOD OF THE SAME

(71) Applicant: TSE CO., LTD., Chungcheongnam-do (KR)

(72) Inventors: Doo Hwan PARK, Chungcheongnam-do (KR); Sung Jun Kim, Chungcheongnam-do (KR); Han Eol Seo, Chungcheongnam-do (KR); Jong Geun Park, Chungcheongnam-do (KR); Kum Sun Park, Chungcheongnam-do (KR); Chung Hyeon Kim, Chungcheongnam-do (KR)

(73) Assignee: TSE CO., LTD., Chungcheongnam-do (KR)

(21) Appl. No.: 17/556,253

(22) Filed: Dec. 20, 2021

(30) Foreign Application Priority Data
May 28, 2021 (KR) 10-2021-0069276

(51) Int. Cl. H05K 3/46; H05K 1/02

(52) U.S. Cl. CPC H05K 3/4688; H05K 1/0298; H05K 3/462; H05K 1/0306

(57) ABSTRACT

A multilayer circuit board including a ceramic substrate part and a unit circuit board coupled to one surface of the ceramic substrate part. The unit circuit board includes an insulating layer with a circuit pattern formed on one side, an adhesive layer adhered to another surface of the insulating layer, a via hole passing through the insulating layer and the adhesive layer and connected to one surface of the circuit pattern, and conductive paste filled in the via hole.

A manufacturing method including batch bonding a circuit board part, which includes a plurality of unit circuit boards, and a ceramic substrate part, wherein each unit circuit board includes providing an insulating layer having a circuit layer, forming an adhesive layer on the insulating layer, forming a circuit pattern, forming a via hole in the insulating and adhesive layers, and filling the via hole with conductive paste.

### CROSS-REFERENCE TO RELATED APPLICATION

This application is based on and claims priority under 35 U.S.C. § 119 to Korean Patent Priority No. 10-2021-0069276 filed on May 28, 2021, in the Korean Intellectual Property Office, the entire disclosure of which is herein incorporated by reference in its entirety.

### BACKGROUND

### Field

Various embodiments of the present disclosure relate to a batch joining type multi-layer circuit board and a manufacturing method of the same.

### Description of Related Art

Multi-layer board development is required because there is a need to increase the number of probe pins, decrease the size of the pad, and provide fine pitch owing to the miniaturization of the semiconductor process and the high integration of devices. Technical and design limitations are being challenged, because of the increasing complexity and density of semiconductor device circuits so that the circuit layer must be increased to expand the test channel.

The increase in the circuit layer increases the turn around time (TAT) and the difficulty of manufacturing the product as well as causing a flatness problem.

The conventional method of manufacturing a multilayer circuit board is to form sequentially a liquid polyimide or polyimide sheet on a ceramic substrate. According to the conventional manufacturing method, each layer of the multi-layer circuit board may be manufactured by repeating the same process. After the first layer of the multi-layer circuit board is manufactured, the same process as that for manufacturing the first layer is repeated, and this may form a second layer on top of the first layer. This method is repeated and may produce third, fourth, and more additional circuit board layers. Specifically, in the process of manufacturing each layer, liquid polyimide coating, a thermal bonding process, a drilling process, a sputtering process, a circuit pattern plating process using dry film photoresist, and an etching process may be performed on one surface of the ceramic substrate.

In a multi-layer circuit board manufactured by a conventional manufacturing method, it is difficult to implement each layer flat. According to the conventional manufacturing method, each thermal bonding process is performed in the manufacturing process of each layer of the multi-layer circuit board. However, since there is a difference in the coefficient of thermal expansion (CTE) between each material, when each material is heated, there is a difference in the degree of expansion and bending of each material due to the occurrence of thermal stress. It becomes difficult to implement each layer flat because of the deformation of the members due to such bending.

In addition, when the multi-layer circuit board is manufactured by the conventional manufacturing method, the manufacturing period becomes relatively long. In the case of manufacturing a circuit board by stacking liquid polyimide layer by layer on a ceramic substrate, as in the conventional manufacturing method, the manufacturing process is repeated as many times as the number of layers as the number of layers increases, so that the manufacturing period of the circuit board becomes longer.

### SUMMARY

A multi-layer circuit board and a method of manufacturing the same according to an embodiment of the present disclosure provide a multi-layer circuit board in which each layer is implemented to be flat by minimizing a thermal bonding process, which reduces the manufacturing period of the multi-layer circuit board.

A multi-layer circuit board according to an embodiment of the present disclosure may include a ceramic substrate part and a unit circuit board coupled to one surface of the ceramic substrate part, wherein the unit circuit board includes an insulating layer with a circuit pattern formed on one side, an adhesive layer adhered to the other surface of the insulating layer, a via hole passing through the insulating layer and the adhesive layer and connected to one surface of the circuit pattern, and a conductive paste filled in the via hole.

A manufacturing method of a batch joining type multi-layer circuit board according to an embodiment of the present disclosure may include manufacturing a circuit board part including a plurality of unit circuit boards, providing a ceramic substrate part, and batch bonding the circuit board part and the ceramic substrate part, wherein manufacturing each unit circuit board includes providing an insulating layer having a circuit layer formed on one surface, forming an adhesive layer adhered to the other surface of the insulating layer, forming a circuit pattern by removing a portion of the circuit layer, forming a via hole that penetrates the insulating layer and the adhesive layer and is connected to one surface of the circuit pattern, and filling the via hole with conductive paste.

The manufacturing method of the batch joining type multi-layer circuit board according to an embodiment of the present disclosure may reduce the manufacturing period of the multi-layer circuit board by making it possible to simultaneously manufacture each layer of the multi-layer circuit board. In addition, the manufacturing method of the batch joining type multi-layer circuit board according to an embodiment of the present disclosure is a method of bonding each layer at the same time, and the thermal process conventionally performed for each layer may be performed only once in the final step. By minimizing the thermal process, the problem caused by bending is alleviated, so that a multi-layer circuit board may be implemented flat.

### BRIEF DESCRIPTION OF THE DRAWINGS

In relation to the description of the drawings, the same or similar reference numerals may be used for the same or similar constituent elements. The above and other aspects, features, and advantages of certain embodiments of the disclosure will be more apparent from the following detailed description, taken in conjunction with the accompanying drawings, in which:

FIG. 1 is a cross-sectional view illustrating a unit circuit board according to an embodiment of the present disclosure.

FIG. 2 is a cross-sectional view illustrating a ceramic substrate part according to an embodiment of the present disclosure.

FIG. 3A is a cross-sectional view illustrating a multi-layer circuit board according to a first embodiment of the present disclosure.

FIG. 3B is a cross-sectional view illustrating a multi-layer circuit board according to a second embodiment of the present disclosure.

FIG. 3C is a cross-sectional view illustrating a multi-layer circuit board according to a third embodiment of the present disclosure.

FIG. 4 is a flowchart illustrating a method of manufacturing a multi-layer circuit board according to an embodiment of the present disclosure.

FIGS. 5A and 5B are explanatory views illustrating a process of manufacturing a unit circuit board according to an embodiment of the present disclosure.

FIG. 6 is a cross-sectional view illustrating a circuit board part and a ceramic substrate part according to an embodiment of the present disclosure.

FIG. 7 is an explanatory view illustrating a state in which a circuit board unit and a ceramic substrate unit are thermocompression bonded according to an embodiment of the present disclosure.

### DETAILED DESCRIPTION

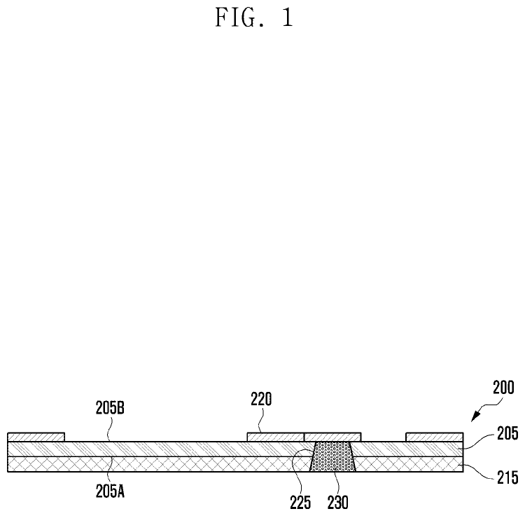

FIG. 1 is a cross-sectional view illustrating a unit circuit board 200 according to an embodiment of the present disclosure.

With reference to FIG. 1, a unit circuit board 200 according to an embodiment of the present disclosure may include an insulating layer 205, an adhesive layer 215, a circuit pattern 220, a via hole 225, or a conductive paste 230, or any combination thereof.

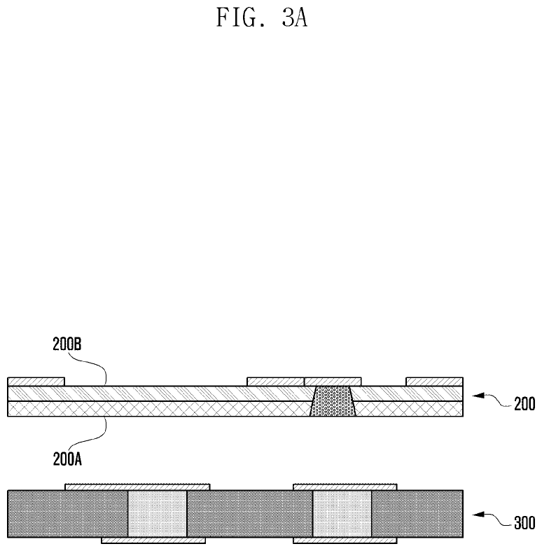

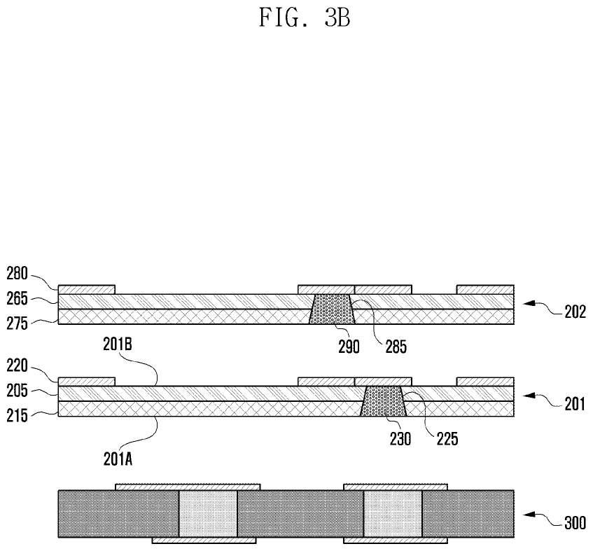

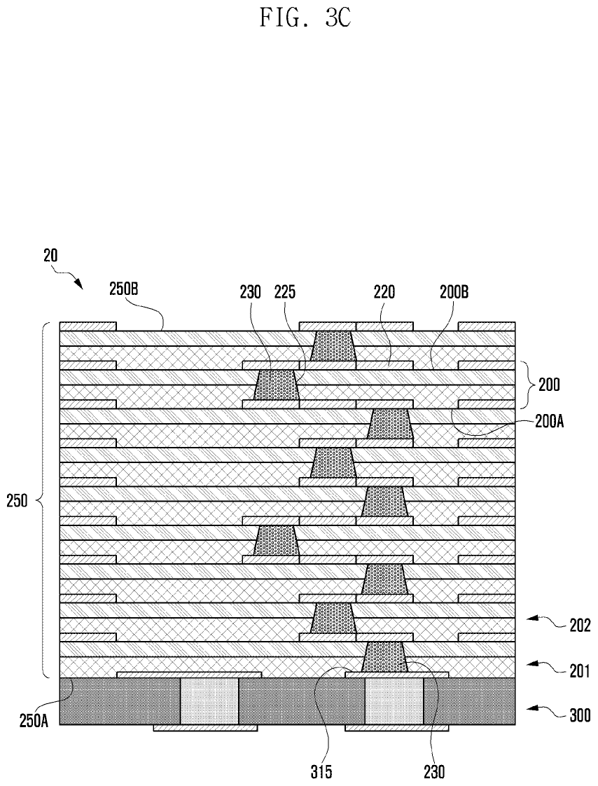

The insulating layer 205 may serve as a board that is the basis of the structure of the unit circuit board 200. The insulating layer 205 may include polyimide. Polyimide has high heat resistance and has excellent electrical properties, chemical stability, etc., so it may be used as the insulating layer 205 of the multilayer circuit board 20 (FIG. 3C).

The insulating layer 205 may have a predetermined thickness and it may be formed to have a uniform thickness.

In various embodiments, the circuit pattern 220 may be coupled to at least a portion of the insulating layer 205. The first surface 205A of the insulating layer 205 may be a lower surface of the insulating layer 205, and the second surface 205B of the insulating layer 205 may be an upper surface of the insulating layer 205. In the insulating layer 205, the circuit pattern 220 may be coupled to the second surface 205B of the insulating layer 205 (e.g., the upper surface of the insulating layer 205).

The circuit pattern 220 may include a conductive material. The circuit pattern 220 may be formed of any one of gold, nickel, and copper or an alloy thereof. The circuit pattern 220 may be preferably made of copper in consideration of electrical conductivity, durability, economic feasibility, etc.

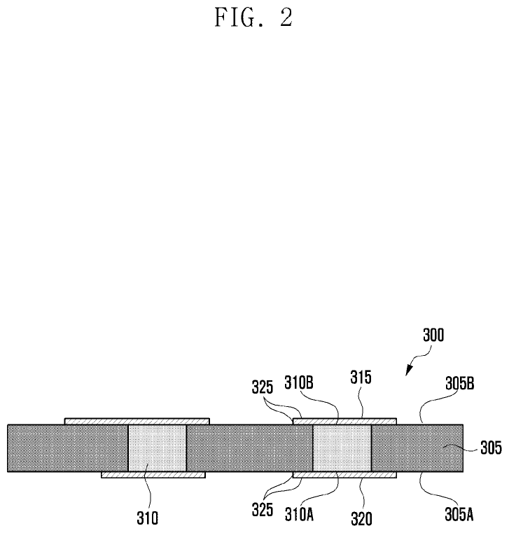

In the insulating layer 205, the adhesive layer 215 may be coupled to the first surface 205A of the insulating layer 205 (e.g., the lower surface of the insulating layer 205). The adhesive layer 215 may bond a plurality of unit circuit boards 200 to each other or the unit circuit board 200 and the ceramic substrate part 300 (FIG. 2).

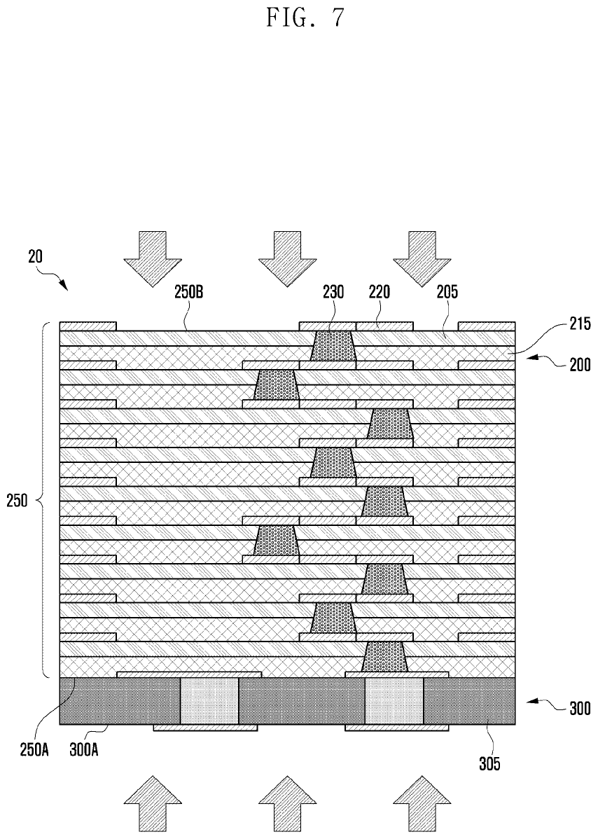

The adhesive layer 215 may include a thermosetting material. The adhesive layer 215 before being heated may include a flowable adhesive material. The adhesive layer 215 may be primarily fixed to the first surface 205A of the insulating layer 205 (e.g., the lower surface of the insulating layer 205) in a fluid state. In the thermocompression step (FIG. 7), the adhesive layer 215 including a thermosetting material may be secondarily cured by heating. The cured adhesive layer 215 may be completely fixed to the insulating layer 205.

The adhesive layer 215 may be formed with a uniform thickness on the first surface 205A of the insulating layer 205 (e.g., the lower surface of the insulating layer 205). The adhesive layer 215 may have a predetermined thickness.

The thickness of the adhesive layer 215 and the thickness of the insulating layer 205 of the unit circuit board 200 may be adjusted according to characteristics of a device in which the unit circuit board 200 is used.

At least a portion of the insulating layer 205 and the adhesive layer 215 may include a via hole 225. The via hole 225 may be connected to all or a part of the circuit pattern 220 formed on one surface of the insulating layer 205.

A plurality of via holes 225 may be formed in the unit circuit board 200. Each of the plurality of via holes 225 may be connected to all or a portion of the circuit pattern 220 formed on the second surface 205B of the insulating layer 205.

The via hole 225 may include a space for filling the conductive paste 230.

The conductive paste 230 may be filled in the via hole 225. The conductive paste 230 may include a conductive material. For example, the conductive paste 230 may include a copper and tin alloy material.

FIG. 2 is a cross-sectional view illustrating a ceramic substrate part 300 according to an embodiment of the present disclosure.

The ceramic substrate part 300 according to an embodiment of the present disclosure may include a ceramic substrate 305, a ceramic through hole 310, an upper conductive layer 315, or a lower conductive layer 320, or any combination thereof.

The ceramic substrate 305 may serve as a substrate that is the basis of the structure of the ceramic substrate part 300. The ceramic substrate 305 may include a ceramic material. Ceramic materials have excellent electrical insulation and mechanical strength, and they may have high thermal resistance and chemical stability.

The ceramic substrate 305 has a similar coefficient of thermal expansion (CTE) to a silicon wafer used for semiconductors; thus, it may be used for testing semiconductors.

The ceramic substrate 305 may include a ceramic through hole 310. A plurality of ceramic through holes 310 may be formed in the ceramic substrate 305. The ceramic through hole 310 may serve to electrically connect the upper conductive layer 315 and the lower conductive layer 320. The ceramic through hole 310 may be formed through mechanical drilling.

In various embodiments, an upper conductive layer 315 and a lower conductive layer 320 may be positioned on at least a portion of the ceramic substrate 305. The first surface 305A of the ceramic substrate 305 may be a lower surface of the ceramic substrate 305, and the second surface 305B of the ceramic substrate 305 may be an upper surface of the ceramic substrate 305. In the ceramic substrate 305, a lower conductive layer 320 may be positioned on the first surface 305A of the ceramic substrate 305 (e.g., the lower surface of the ceramic substrate 305). In the ceramic substrate 305, an upper conductive layer 315 may be positioned on the second surface 305B of the ceramic substrate 305 (e.g., the upper surface of the ceramic substrate 305).

The upper conductive layer 315 and the lower conductive layer 320 may include a circuit pattern 325. The circuit pattern 325 may be formed through a photolithography process, a plating process, an etching process, etc.

The upper conductive layer 315 and the lower conductive layer 320 may include a conductive material. The upper conductive layer 315 and the lower conductive layer 320 may be made of any one of copper, nickel, and gold or an alloy thereof, and they may be preferably made of copper in consideration of electrical conductivity, durability, economic feasibility, etc.

The first opening 310A of the ceramic through hole 310 may be a lower opening of the ceramic through hole 310, and the second opening 310B may be an upper opening of the ceramic through hole 310. The lower conductive layer 320 may be formed in the first opening 310A of the ceramic through hole 310 (e.g., the lower opening of the ceramic through hole 310). The upper conductive layer 315 may be formed in the second opening 310B of the ceramic through hole 310 (e.g., the upper opening of the ceramic through hole 310).

FIGS. 3A, 3B, and 3C are cross-sectional views illustrating a multi-layer circuit board 20 according to an exemplary embodiment of the present disclosure.

FIG. 3A is a cross-sectional view illustrating an arrangement of a unit circuit board 200 and a ceramic substrate part 300 according to an embodiment of the present disclosure. FIG. 3B is a cross-sectional view illustrating a state in which two unit circuit boards 200 and a ceramic substrate part 300 are disposed according to an embodiment of the present disclosure. FIG. 3C is a cross-sectional view illustrating a multi-layer circuit board 20 including a plurality of unit circuit boards 200 and a ceramic substrate part 300 according to an embodiment of the present disclosure.

With reference to FIG. 3A, the multi-layer circuit board 20 (FIG. 3C) according to an embodiment of the present disclosure may include one unit circuit board 200 and a ceramic substrate part 300.

The first surface 200A of the unit circuit board 200 may be a lower surface of the unit circuit board 200, and the second surface 200B of the unit circuit board 200 may be an upper surface of the unit circuit board. In the unit circuit board 200, the ceramic substrate part 300 may be positioned on the first surface 200A of the unit circuit board 200 (e.g., the lower surface of the unit circuit board 200).

With reference to FIG. 3B, the multi-layer circuit board 20 (FIG. 3B) according to an embodiment of the present disclosure may include two unit circuit boards 200 (FIG. 1) and a ceramic substrate part 300 (FIG. 2). For example, the multi-layer circuit board 20 (FIG. 3B) may include a first circuit board 201, a second circuit board 202, and a ceramic substrate part 300.

The first circuit board 201 may include an insulating layer 205, an adhesive layer 215, a circuit pattern 220, a via hole 225, or a conductive paste 230, or any combination thereof.

In various embodiments, the second circuit board 202 or the ceramic substrate part 300 may be coupled to at least a portion of the first circuit board 201. The first surface 201A of the first circuit board 201 may be a lower surface of the first circuit board 201, and the second surface 201B of the first circuit board 201 may be an upper surface of the first circuit board 201. The second circuit board 202 may be positioned on the second surface 201B of the first circuit board 201 (e.g., the upper surface of the first circuit board 201). In the first circuit board 201, the ceramic substrate part 300 may be positioned on the first surface 201A of the first circuit board 201 (e.g., the lower surface of the first circuit board 201).

The second circuit board 202 may include an insulating layer 265, an adhesive layer 275, a circuit pattern 280, a via hole 285, or a conductive paste 290 or any combination thereof.

The insulating layer 265, the adhesive layer 275, the circuit pattern 280, the via hole 285 and the conductive paste 290 of the second circuit board 202 may function the same as each of the insulating layer 205, the adhesive layer 215, the circuit pattern 220, the via hole 225, and the conductive paste 230, respectively, of the first circuit board 201.

With reference to FIG. 3C, the multi-layer circuit board 20 according to an embodiment of the present disclosure may include a plurality of unit circuit boards 200 and a ceramic substrate part 300.

With reference to FIG. 3C, the circuit board part 250 may include a first circuit board 201, a second circuit board 202, and one or more additional unit circuit boards 200. That is, the circuit board part 250 according to an embodiment of the present disclosure may include a plurality of unit circuit boards 200.

In various embodiments, the ceramic substrate part 300 may be coupled to at least a portion of the circuit board part 250. The first surface 250A of the circuit board part 250 may be the lowermost surface of the circuit board part 250, and the second surface 250B may be the uppermost surface of the circuit board part 250. The ceramic substrate part 300 may be coupled to the first surface 250A of the circuit board part 250 (e.g., the lowermost surface of the circuit board part 250).

A plurality of unit circuit boards 200 may be stacked and disposed. In various embodiments, another unit circuit board 200 may be coupled to at least a portion of the unit circuit board 200. The first surface 200A of the unit circuit board 200 may be a lower surface of the unit circuit board 200, and the second surface 200B of the unit circuit board 200 may be an upper surface of the unit circuit board. Another unit circuit board 200 may be coupled to the first surface 200A (e.g., the lower surface of the unit circuit board 200) or the second surface 200B of the unit circuit board 200 (e.g., the upper surface of the unit circuit board 200).

In FIG. 3C, each unit circuit board 200 includes only one via hole 225 and one conductive paste 230, but the number of via holes 225 and conductive pastes 230 is not limited thereto. That is, each unit circuit board 200 may include a plurality of via holes 225 and conductive pastes 230.

The conductive paste 230 may be formed at a position where it meets all or part of the circuit pattern 220 included in each unit circuit board 200. For example, the conductive paste 230 may be formed at a position where the circuit pattern 220 is formed on the second surface 200B (upper surface) of the unit circuit board 200 and the circuit pattern 220 of another unit circuit board 200 is located on the first surface 200A (lower surface) of the unit circuit board 200. The conductive paste 230 and the circuit pattern 220 may contact each other to electrically connect each unit circuit board 200.

The upper conductive layer 315 of the ceramic substrate part 300 may be formed at the location where it meets a conductive paste 230 included in the first surface 250A of the circuit board part 250 (e.g., the lower surface of the circuit board part 250). The conductive paste 230 and the upper conductive layer 315 may contact and electrically connect the ceramic substrate part 300 and the circuit board part 250.

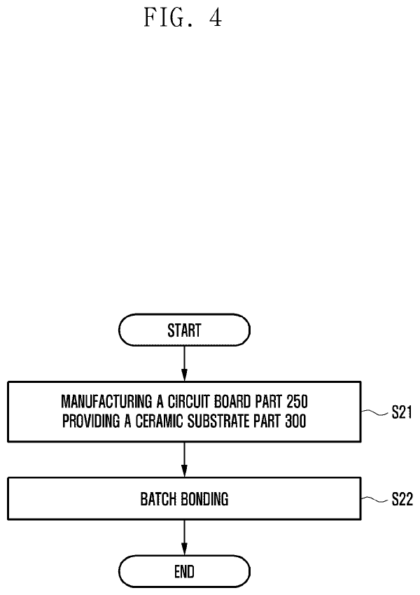

FIG. 4 is a flowchart illustrating a method of manufacturing a multi-layer circuit board 20 (FIG. 3C) according to an embodiment of the present disclosure.

With reference to FIG. 4, a method of manufacturing a multi-layer circuit board 20 (FIG. 3C) according to an embodiment of the present disclosure includes manufacturing the circuit board part 250 (FIG. 3C) and providing the ceramic substrate part 300 (FIG. 2) (S21) and bonding the circuit board part 250 (FIG. 3C) and the ceramic substrate part 300 (FIG. 2) together (S22).

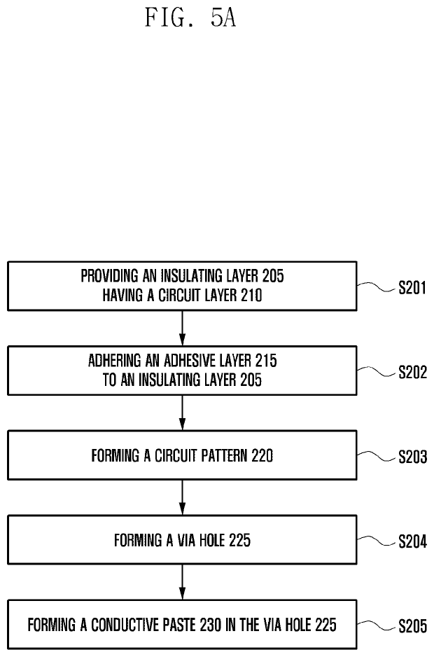

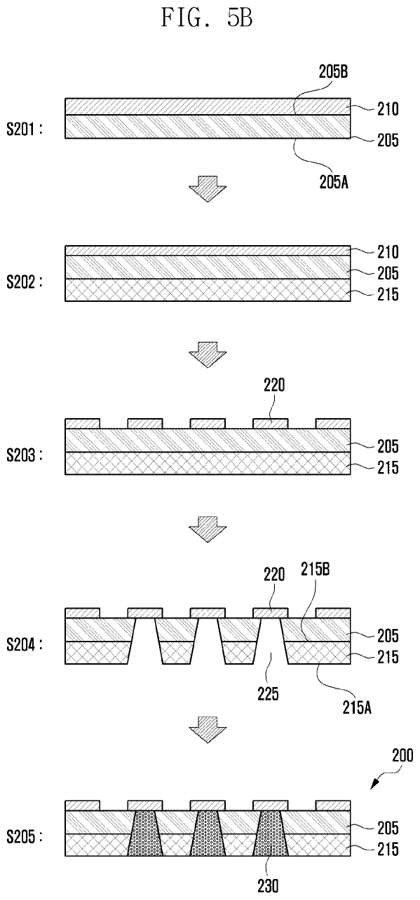

In step S21, the circuit board part 250 (FIG. 3C) may be manufactured. Since the circuit board part 250 includes a plurality of unit circuit boards 200 (FIG. 1), the process of manufacturing the unit circuit board 200 (FIGS. 5A and 5B) is repeated to manufacture the circuit board part 250 (FIG. 3C).

In step S21, a ceramic substrate unit 300 (FIG. 2) may be provided. The ceramic substrate part 300 (FIG. 2) may be a ceramic substrate 305 (FIG. 2), a ceramic through hole 310 (FIG. 2), an upper conductive layer 315 (FIG. 2), and a lower conductive layer 320 or any combination thereof (FIG. 2).

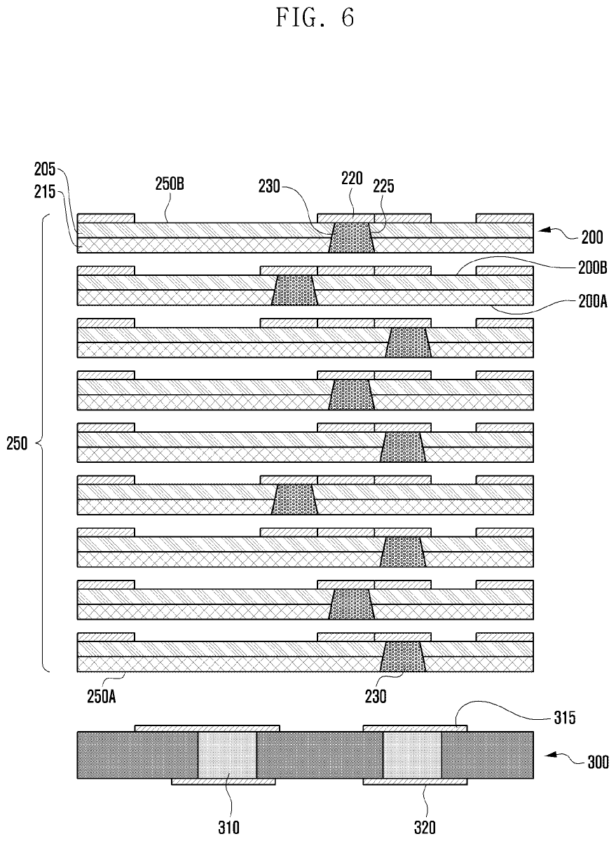

In step S22, the circuit board part 250 (FIG. 6) and the ceramic substrate part 300 (FIG. 6) may be bonded together. A circuit board part 250 (FIG. 6) and a ceramic substrate part 300 (FIG. 6) may be disposed for bonding. The arranged circuit board part 250 (FIG. 7) and the ceramic substrate part 300 (FIG. 7) may be thermocompression bonded using a press device (not shown) to be collectively bonded (FIG. 7).

FIGS. 5A and 5B are explanatory views illustrating a process of manufacturing a unit circuit board according to an embodiment of the present disclosure.

FIG. 5A is a flowchart illustrating a manufacturing process of the unit circuit board 200 according to an embodiment of the present disclosure. FIG. 5B is an explanatory diagram illustrating a process in which the unit circuit board 200 is manufactured according to the sequence shown in FIG. 5A.

With reference to FIGS. 5A and 5B, a method of manufacturing a unit circuit board 200 according to an embodiment of the present disclosure may include providing an insulating layer 205 having a circuit layer 210 formed on one surface (S201), adhering an adhesive layer 215 to the other surface of the insulating layer 205 (S202), forming a circuit pattern 220 by removing a portion of the circuit layer 210 through an etching process (S203), forming a via hole 225 connected to the circuit pattern 220 through the insulating layer 205 and the adhesive layer 215 (S204), and filling a conductive paste 230 in the via hole 225 (S205).

In step S201, an insulating layer 205 having a circuit layer 210 formed on one surface may be provided. The insulating layer 205 may include polyimide. Polyimide has high heat resistance and has excellent electrical properties and chemical resistance, so it may be used as an insulating layer of the unit circuit board 200.

The insulating layer 205 may couple the circuit layer 210 to one surface. For example, the circuit layer 210 may be coupled to the second surface 205B of the insulating layer 205 (e.g., the upper surface of the insulating layer 205).

The circuit layer 210 may be bonded to the second surface 205B of the insulating layer 205 (e.g., the upper surface of the insulating layer 205) using a press method. Among the press methods, a hot press method in which heat and pressure are applied may be used.

The circuit layer 210 may be made of any one of gold, silver, copper, and aluminum or an alloy thereof. The circuit layer 210 may be preferably made of copper in consideration of electrical conductivity, durability, economic feasibility, etc.

The circuit layer 210 may be formed with a uniform thickness on the second surface 205B of the insulating layer 205 (e.g., the upper surface of the insulating layer 205). The circuit layer 210 may have a predetermined thickness.

According to the method of manufacturing the unit circuit board 200 according to an embodiment of the present disclosure, the insulating layer 205 and the adhesive layer 215 may be separately manufactured. This method may have an advantage in that the thickness of the insulating layer 205 may be flexibly adjusted compared with a method of manufacturing the insulating layer 205 by including an adhesive material inside.

In step S202, the adhesive layer 215 may be bonded to the first surface 205A of the insulating layer 205 (e.g., the lower surface of the insulating layer 205).

The adhesive layer 215 may include a thermosetting material. The adhesive layer 215 including a thermosetting material may be firstly adhered to the first surface 205A of the insulating layer 205 in a semi-cured state, and then may be secondary cured through a thermocompression bonding process to be completely adhered.

In operation S203, at least a portion of the circuit layer 210 formed on the second surface 205B of the insulating layer 205 may be removed to form a circuit pattern 220.

The circuit pattern 220 may be formed using a photolithography process and an etching process. The photolithography process may include a photoresist application process, an exposure process, and a developing process. The photoresist application process may include a process of applying a photoresist solution, which is a material sensitive to light, to the circuit layer 210 before irradiating light to the circuit layer 210. The exposure process may include a process of selectively irradiating light after a mask on which a pattern is formed is covered on the circuit layer 210. The developing process may include a process of applying a developer to the circuit layer 210 to distinguish a portion irradiated with light from a portion not irradiated with light. After the photolithography process, a portion of the circuit layer 210 except for the circuit pattern 220 may be removed through an etching process to form the circuit pattern 220.

Precise positions and dimensions of the circuit pattern 220 may be designed in advance in consideration of a relationship with another unit circuit board 200 that may be disposed on one surface of the circuit pattern 220.

In operation S204, a via hole 225 connected to the circuit pattern 220 may be formed through the insulating layer 205 and the adhesive layer 215.

In various embodiments, the adhesive layer 215 may include a via hole 225 in at least a portion of the adhesive layer 215. The first surface 215A of the adhesive layer 215 may be a lower surface of the adhesive layer 215, and the second surface 215B of the adhesive layer 215 may be an upper surface of the adhesive layer 215. The via hole 225 may be formed in the first surface 215A of the adhesive layer 215 (e.g., the lower surface of the adhesive layer 215) through a drilling method.

The via hole 225 according to an embodiment of the present disclosure may be formed using a laser drill. A UV (ultra violet) laser drill may be used to form the minute via hole 225.

The insulating layer 205 may include a via hole 225 formed in the adhesive layer 215. That is, the via hole 225 may be formed starting from the first surface 215A of the adhesive layer 215 (e.g., the lower surface of the adhesive layer 215) and connected to the insulating layer 205.

The via hole 225 may be connected to the circuit pattern 220 located on the second surface 205B of the insulating layer 205 (e.g., the upper surface of the insulating layer 205). The via hole 225 may be connected to all or part of the circuit pattern 220.

The via hole 225 may include a space for filling the conductive paste 230. Each unit circuit board 200 may be electrically connected when the via hole 225 is filled with a conductive paste 230 that is a conductive material.

The unit circuit board 200 may include a plurality of via holes 225. In FIG. 5B, the unit circuit board 200 includes three via holes 225, but the number of via holes 225 is not limited thereto.

The method of manufacturing the unit circuit board 200 according to an embodiment of the present disclosure may include a process of cleaning the inside of the via hole 225 after the via hole 225 is formed. A cleaning process using plasma may be used to clean the inside of the via hole 225. The cleaning process may remove dust generated in the process of forming the via hole 225 to facilitate filling the conductive paste 230 into the via hole 225 in step S205.

In step S205, the conductive paste 230 may be filled in the via hole 225.

The conductive paste 230 may include a conductive material. The conductive paste 230 is formed at a position connected to the circuit pattern 220 formed on each unit circuit board 200, and it may electrically connect the circuit patterns 220 of each unit circuit board 200.

The conductive paste 230 may be filled by pushing the conductive paste 230 into the via hole 225. In order to push the conductive paste 230 into the via hole 225, a member capable of applying pressure to the conductive paste 230 such as a squeezer (not shown) may be used.

When all the manufacturing processes of steps S201, S202, S203, S204, and S205 are performed, the unit circuit board 200 shown in step S22 of FIG. 4 may be manufactured. The unit circuit board 200 may include an insulating layer 205 and an adhesive layer 215. The unit circuit board 200 may include a circuit pattern 220 on the second surface 205B of the insulating layer 205 (e.g., the upper surface of the insulating layer 205). The insulating layer 205 and the adhesive layer 215 may include via holes 225. The conductive paste 230 may be filled in the via hole 225.

FIG. 6 is a cross-sectional view illustrating a circuit board part 250 and a ceramic substrate part 300 according to an embodiment of the present disclosure.

In various embodiments, a plurality of unit circuit boards 200 may be disposed to be spaced apart from each other. The first surface 200A of the unit circuit board 200 may be a lower surface of the unit circuit board 200, and the second surface 200B of the unit circuit board 200 may be an upper surface of the unit circuit board. On the first surface 200A of the unit circuit board 200 (e.g., the lower surface of the unit circuit board 200) or the second surface 200B (e.g., the upper surface of the unit circuit board 200), other unit circuit boards 200 may be spaced apart from each other.

FIG. 6 illustrates that each unit circuit board 200 includes only one via hole 225 and one conductive paste 230, but the number of via holes 225 and conductive pastes 230 is not limited thereto.

The conductive paste 230 may be formed at a position where it may meet all or part of the circuit pattern 220 included in each unit circuit board 200. For example, the conductive paste 230 may be formed at a position where it may meet the circuit pattern 220 formed on the second surface 200B (upper surface) of the unit circuit board 200 and the circuit pattern 220 of another unit circuit board 200 spaced apart from the first surface 200A (lower surface) of the unit circuit board 200.

In various embodiments, the circuit board part 250 may include a plurality of unit circuit boards 200 spaced apart from each other. The first surface 250A of the circuit board part 250 may be the lowermost surface of the circuit board part 250, and the second surface 250B may be the uppermost surface of the circuit board part 250. The ceramic substrate part 300 may be positioned at a distance from the first surface 250A of the circuit board part 250 (e.g., the lowermost surface of the circuit board part 250).

The upper conductive layer 315 of the ceramic substrate part 300 may be formed in a position where it may meet the conductive paste 230 connected to the first surface 250A of the circuit board part 250 (e.g., the lowermost surface of the circuit board part 250).

The positions of each unit circuit board 200 and the ceramic substrate part 300 may be temporarily fixed using a support member (not shown). A hole (not shown) for temporarily coupling the support member (not shown) may be formed at one side and the other side of each unit circuit board 200 and the ceramic substrate part 300. The support member (not shown) may be temporarily coupled to the hole (not shown) to align each unit circuit board 200 and the ceramic substrate part 300 at a spaced apart distance from each other.

FIG. 7 is an explanatory view illustrating a state in which the circuit board part 250 and the ceramic substrate part 300 are thermocompression bonded according to an embodiment of the present disclosure.

A press device (not shown) may be located on a second surface 250B of the circuit board part 250 (e.g., the top surface of the circuit board part 250) and a first surface 300A of the ceramic substrate part 300 (e.g., the lower surface of the ceramic substrate part 300).

The press device (not shown) may be a hot press device, and it may apply heat and pressure to the second surface 250B (topmost surface) of the circuit board part 250 and the first surface 300A (lower surface) of the ceramic substrate part 300. Heat and pressure generated by the press device (not shown) may be transferred to each unit circuit board 200. Through the transferred heat and pressure, the gap between each unit circuit board 200 is eliminated and compression may be performed.

The adhesive layer 215 is cured by heat and pressure, and it may completely adhere each unit circuit board 200 and the ceramic substrate part 300.

The conductive paste 230 may perform a sintering action by receiving heat and pressure. That is, through the heat and pressure generated by the press device (not shown), the conductive paste 230 may change from a powder state to an alloy state, thereby having the mechanical strength required for the configuration of the multi-layer circuit board 20.

After completing the thermocompression bonding through the press device, the support member (not shown) temporarily coupled to one side and the other side of each unit circuit board 200 and the ceramic substrate part 300 may be removed.

Although the embodiments of the present disclosure have been described above, the present disclosure is not necessarily limited thereto, and modifications and variations are possible within the scope of the technical spirit of the present disclosure.

DESCRIPTION OF REFERENCE NUMERALS

| | |
|---|---|
| 20: multi-layer circuit board | 200: unit circuit board |
| 205: insulating layer | 210: circuit layer |
| 215: adhesive layer | 220: circuit pattern |
| 225: via hole | 230: conductive paste |
| 250: circuit board part | 300: ceramic substrate part |
| 305: ceramic substrate | 310: ceramic through hole |
| 315: upper conductive layer | 320: lower conductive layer |
| 200A: first surface of unit circuit board | |
| 200B: second surface of unit circuit board | |
| 205A: first surface of insulating layer | |
| 205B: second surface of insulating layer | |
| 250A: first surface of circuit board part | |
| 250B: second surface of circuit board part | |
| 300A: first surface of ceramic board part | |
| 300B: second surface of ceramic board part | |
| 305A: first surface of ceramic board | 305B: second surface of |
| 310A: first opening of ceramic through hole | ceramic board |
| 310B : second opening of ceramic through | |
| hole | |

We claim:

1. A multi-layer circuit board comprising:
a ceramic substrate part; and
a unit circuit board coupled to one surface of the ceramic substrate part, wherein the unit circuit board comprises:
an insulating layer with a circuit pattern formed on a first side of the insulating layer;
an adhesive layer adhered to a second surface of the insulating layer;
a via hole passing through the insulating layer and the adhesive layer and connected to one surface of the circuit pattern; and
a conductive paste filled in the via hole.

2. The multi-layer circuit board of claim 1 comprises a second unit circuit board.

3. The multi-layer circuit board of claim 1, wherein the insulating layer is made of polyimide.

4. The multi-layer circuit board of claim 1, wherein the circuit pattern is made of copper.

5. The multi-layer circuit board of claim 1, wherein the unit circuit board comprises a second via hole.

6. A manufacturing method of a batch joining type multi-layer circuit board, the manufacturing method comprising:
manufacturing a circuit board part comprising a plurality of unit circuit boards;
providing a ceramic substrate part; and
batch bonding the circuit board part and the ceramic substrate part;
wherein manufacturing each of the plurality of unit circuit boards comprises:
providing an insulating layer comprising a circuit layer formed on a first surface of the insulating layer;
forming an adhesive layer adhered to a second surface of the insulating layer;
forming a circuit pattern by removing a portion of the circuit layer;
forming a via hole that penetrates the insulating layer and the adhesive layer and is connected to one surface of the circuit pattern; and
filling the via hole with conductive paste.

7. The manufacturing method of the batch joining type multi-layer circuit board of claim 6, wherein the insulating layer is made of polyimide.

8. The manufacturing method of the batch joining type multi-layer circuit board of claim 6, comprising adjusting a thickness of the insulating layer.

9. The manufacturing method of the batch joining type multi-layer circuit board of claim 6, wherein the circuit layer is made of copper.

10. The manufacturing method of the batch joining type multi-layer circuit board of claim 6, wherein an etching process is used after a photolithography process to remove a portion of the circuit layer.

11. The manufacturing method of the batch joining type multi-layer circuit board of claim 6, wherein the unit circuit board comprises a second via hole.

12. The manufacturing method of the batch joining type multi-layer circuit board of claim 6, wherein the via hole is formed using a laser drill.

13. The manufacturing method of the batch joining type multi-layer circuit board of claim 6 further comprising cleaning the via hole after the forming of the via hole.

14. The manufacturing method of the batch joining type multi-layer circuit board of claim 6, wherein batch bonding comprises:
fixing a first side and a second side of the circuit board part and a third side and a fourth side of the ceramic substrate with a support member;
bonding the circuit board part and the ceramic substrate part by heating and pressing one surface of the circuit board part and one surface of the ceramic substrate part; and
removing the support member.
